(19) United States
(12) Patent Application Publication
(10) Pub. No.: US 2022/0386422 A1
(43) Pub. Date: Dec. 1, 2022

(54) HEATING BODY OF EPITAXIAL GROWTH DEVICE

(71) Applicants: ZHEJIANG QIUSHI SEMICONDUCTOR EQUIPMENT CO., LTD, Hangzhou (CN); ZHEJIANG JINGSHENG M & E CO., LTD, Shaoxing (CN)

(72) Inventors: Wenjie SHEN, Hangzhou (CN); Liang ZHU, Hangzhou (CN); Jiancan ZHOU, Hangzhou (CN); Jiafeng CHENG, Hangzhou (CN); Qiucheng ZHANG, Hangzhou (CN); Linjian FU, Hangzhou (CN); Jianwei CAO, Hangzhou (CN); Kui YANG, Hangzhou (CN)

(21) Appl. No.: 17/726,542

(22) Filed: Apr. 22, 2022

Related U.S. Application Data
(63) Continuation of application No. PCT/CN2022/077688, filed on Feb. 24, 2022.

(30) Foreign Application Priority Data
Jun. 1, 2021 (CN) 202110606975.9

(51) Int. Cl. H05B 6/06; H05B 6/10; C23C 16/458

(52) U.S. Cl. CPC H05B 6/06; H05B 6/105; C23C 16/4586

(57) ABSTRACT

A heating body of an epitaxial growth device is provided. The heating body (1) includes a supporting base (11) and a tray (2). The supporting base (11) extends along an axis of the epitaxial growth device (100). The tray (2) is mounted on the supporting base (11) to support a substrate. The supporting base (11) is configured to generate heat by an electromagnetic induction with an induction coil, which in turn heats the tray (2). The tray (2) is configured to transfer heat to the substrate to heat the substrate. The supporting base (11) is provided with a temperature control channel (3), which is close to an edge of the tray (2), and along a direction perpendicular to a surface of the supporting base (11), a part of a projection of the temperature control channel (3) is on the tray (2).

### CROSS-REFERENCE TO RELATED APPLICATION

This application is a continuation of international application No. PCT/CN2022/077688 filed on Feb. 24, 2022, which claims all benefits accruing from China Patent Application No. 202110606975.9, filed on Jun. 1, 2021, titled “HEATING BODY OF EPITAXIAL GROWTH DEVICE” in the China National Intellectual Property Administration, the content of which is hereby incorporated by reference.

### TECHNICAL FIELD

The present disclosure generally relates to epitaxial growth of semiconductor, and in particular, to a heating body of an epitaxial growth device.

### BACKGROUND

Epitaxial growth is an important part of a semiconductor industry chain, and quality of an epitaxial film (i.e. an epitaxial layer) directly affects the performance of a subsequent device. With an increasing demand for a semiconductor device with high quality in the industry, an epitaxial device with high efficiency and high quality is gaining more and more attention.

Epitaxial growth mainly refers to growth of a high quality epitaxial film on a substrate. The epitaxial film can be prepared by a plurality of methods, among which chemical vapor deposition (CVD) is most widely used. The CVD refers to a method to synthesize coatings or nano-materials via reaction of chemical gases or vapors on a surface of the substrate. Two or more gaseous raw materials are introduced into a reaction chamber of a heating body of an epitaxial growth device, a conventional reaction chamber of the epitaxial growth device is formed by a plurality of heating bases combined and part of the heating bases are configured to support the substrate. A chemical reaction may occur between reaction gases to form a new material that is deposited on the surface of the substrate. A temperature of the heating bases is one of important factors affecting a deposition rate, and temperature distributions of the heating bases and the substrate directly affect thickness uniformity and doping uniformity of the epitaxial layer.

At present, the epitaxial growth device with a plurality of reaction chambers has a disadvantage that among the reaction chambers, the temperature distribution of the plurality of heating bases configured to support the substrate varies greatly, and the temperature distribution of the substrate is hardly controlled, which greatly affects quality of productions.

### SUMMARY

Thus, it is desired to provide a heating body of an epitaxial growth device to solve above problem.

The heating body of the epitaxial growth device provided in the present disclosure includes a supporting base and a tray. The supporting base includes at least one temperature control channel which is hollow and penetrates through the supporting base along an axis of the epitaxial growth device. The tray is mounted on the supporting base to support a substrate. The temperature control channel is configured to accommodate a temperature control medium, and the temperature control medium is able to be input and output via two ends of the temperature control channel respectively, so as to control an environment temperature of the tray.

In an embodiment of the present disclosure, the temperature control channel is close to an edge of the tray, and along a direction perpendicular to a surface of the supporting base, a part of a projection of the temperature control channel is on the tray.

In an embodiment of the present disclosure, the supporting base includes one temperature control channel, and a part of the temperature control channel is in a ring shape.

In an embodiment of the present disclosure, the temperature control channel successively includes a first segment, a second segment, and a third segment, which are in communication with each other. The second segment is in a ring shape, and the second segment is close to an edge of the tray.

In an embodiment of the present disclosure, the supporting base includes two temperature control channels, and the two temperature control channels are disposed corresponding to two sides of the tray respectively.

In an embodiment of the present disclosure, the supporting base includes an air floating channel which is located between the two temperature control channels, and the two temperature control channels are symmetrically arranged with the air floating channel as an axis.

In an embodiment of the present disclosure, the supporting base includes a first portion and a second portion, the first portion includes a first groove, the second portion includes a second groove, the first groove and the second groove are matched with each other, and the temperature control channel is defined by the first groove and the second groove.

In an embodiment of the present disclosure, a flow rate of cooling medium flowing into the temperature control channel is less than 1 L/min.

In an embodiment of the present disclosure, the heating body includes a plurality of supporting bases, the plurality of the supporting bases are sequentially arranged along a direction perpendicular to the axis of the epitaxial growth device.

In an embodiment of the present disclosure, the heating body further includes a supporting member disposed between adjacent two supporting bases.

The present disclosure further provides an epitaxial growth device including any one of the above heating bodies of the epitaxial growth device.

The heating body of the epitaxial growth device provided in the present disclosure has the following advantages compared to related technologies.

In the present disclosure, the temperature control channel is disposed in the supporting base and capable of controlling temperature of a local region of the tray corresponding to the temperature control channel. A temperature of the substrate can be equalized to ensure thickness uniformity and doping uniformity of an epitaxial layer generated on the substrate, improving quality of productions. The temperature control medium can flow into the temperature control channel to control relative temperatures among the plurality of the supporting bases, so as to reduce temperature differences among a plurality of trays. Temperature distribution of a plurality of substrates can be uniform and consistent, and a variation of the same batch of productions can be reduced.

### BRIEF DESCRIPTION OF THE DRAWINGS

FIG. 1 is a schematic diagram of a part of an epitaxial growth device in an embodiment of the present disclosure.

FIG. 2 is a left side cross-sectional diagram of the epitaxial growth device of FIG. 1.

FIG. 3 is a normal cross-sectional diagram of the epitaxial growth device of FIG. 1.

FIG. 4 is a top cross-sectional diagram of the epitaxial growth device of FIG. 1.

FIG. 5 is a left side cross-sectional diagram of the supporting base of FIG. 1.

In the figures, 100 represents an epitaxial growth device; 1 represents a heating body; 11 represents a supporting base; 111 represents a first portion; 111a represents a first groove; 112 represents a second portion; 112a represents a second groove; 12 represents a sub-heating base; 121 represents a first sub-heating base; 122 represents a second sub-heating base; 123 represents a third sub-heating base; 13 represents a mounting groove; 14 represents a locating column; 2 represents a tray; 3 represents a temperature control channel; 4 represents an air floating channel; 5 represents a reaction chamber; 6 represents a supporting member; 7 represents a through hole; 8 represents a heat retaining cylinder; 81 represents a first heat retaining felt; 82 represents a second heat retaining felt; 83 represents an end cap; 84 represents a first step; 85 represents a second step.

The present disclosure will be further described in conjunction with the figures and the embodiments hereinafter.

### DETAILED DESCRIPTION OF THE EMBODIMENT

The technical solutions in the embodiments of the present disclosure are clearly and completely described in the following with reference to the accompanying drawings in the embodiments of the present disclosure. It is obvious that the described embodiments are only a part of the embodiments, but not all of the embodiments. All other embodiments obtained by those skilled in the art based on the embodiments of the present disclosure without making creative labor are the scope of the present disclosure.

It should be noted that when an element is considered to be “disposed on” another element, it can be directly disposed to another element, or there can be a centered element. When an element is considered to be “set on” another element, it can be directly set on another element, or there can be a centered element at the same time. When an element is considered to be “fixed to” another element, it can be directly fixed to another element, or there can be a centered element at the same time.

Unless otherwise defined, all technical and scientific terms used herein have the same meaning as a skilled person in the art would understand. The terminology used in the description of the present disclosure is for the purpose of describing particular embodiments and is not intended to limit the disclosure. The term “or/and” as used herein includes any and all combinations of one or more of the associated listed items.

In the present disclosure, an epitaxial growth device 100 can include a heating body 1 and an induction coil. The induction coil can be disposed around outside the heating body 1, and the heating body 1 can be excited by an electromagnetic induction of the induction coil and generate heat to heat a substrate. In other embodiments, the heating body 1 is not limited to be heated by the above method. For example, the heating body can also be heated by electrical energy, which will not be limited herein.

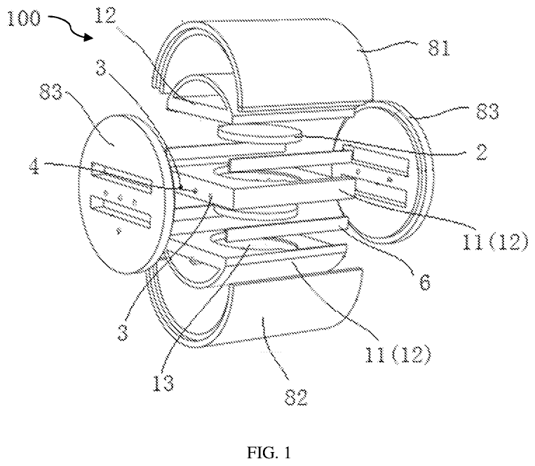

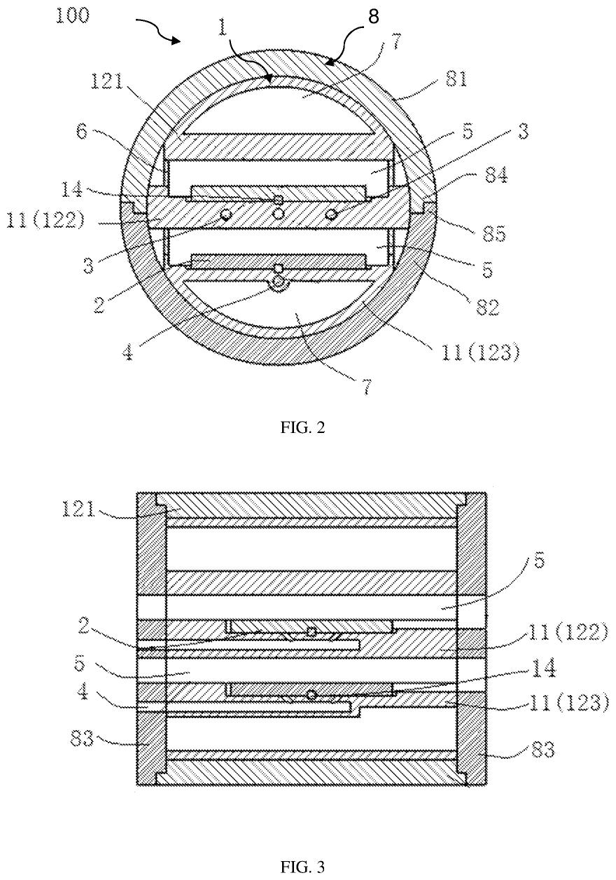

Referring to FIG. 1 to FIG. 4, the heating body 1 of the epitaxial growth device 100 provided in the present disclosure can include a supporting base 11 and a tray 2. The supporting base 11 can extend along a direction of an axis of the epitaxial growth device 100. The tray 2 can be mounted on the supporting base 11 to support a substrate. The supporting base 11 can generate heat by the electromagnetic induction of the induction coil to heat the tray 2, and the tray 2 can transmit heat to the substrate to heat the substrate. The supporting base 11 has a temperature control channel 3, and a temperature control medium can be transferred into the temperature control channel 3. The temperature control medium can be a cooling medium or a heating medium to control a temperature around the temperature control channel 3 and control a temperature of a local area on the tray 2.

Relative temperatures among a plurality of supporting bases 11 can be controlled by the temperature control channel 3 to reduce temperature differences among a plurality of trays 2, so as to ensure that temperature distribution of a plurality of substrates can be uniform and consistent and a variation of the same batch of productions can be reduced. A temperature of an area around the temperature control channel 3 on the tray 2 can also be controlled by designing the temperature control channel 3. A temperature of each area on the tray 2 can be equalized, resulting in that an epitaxial layer on the substrate can grow uniformly with uniform thickness, effectively improving quality of productions.

Specifically, the temperature control channel 3 can be close to an edge of the tray 2, and along a direction perpendicular to a surface of the supporting base 11, a part of a projection of the temperature control channel 3 can be on the tray 2. A temperature of the edge of the tray 2 corresponding to the temperature control channel 3 can be controlled by the temperature control channel 3. A temperature difference between the edge of the tray 2 and a center of the tray 2 can be reduced. A temperature of the edge of the tray 2 and a temperature of the center of the tray 2 can be equalized, thereby ensuring thickness uniformity of an edge of the epitaxial layer and a center of the epitaxial layer and doping uniformity of the epitaxial layer generated on the substrate, and improving quality of the productions.

Alternatively, in an embodiment of the present disclosure, the supporting base 11 can include one temperature control channel 3, and a part of the temperature control channel 3 is in a ring shape. The temperature control channel 3 in a ring shape can be surrounded corresponding to the edge of the tray 2. When the cooling medium flows into the temperature control channel 3, the temperature of the edge of the tray 2 can be reduced, so that the temperature of the edge of the tray 2 and the temperature of the center of the tray 2 can tend to be the same, ensuring uniformity of temperature distribution between the edge of the tray 2 and the center of the tray 2. A controlling of the temperature of the substrate is conducive to improving quality of the epitaxial layer.

In other embodiments, a specific structure of the temperature control channel 3 and a number of the temperature control channel 3 are not limited to those in the above embodiment. For example, the supporting base 11 can includes a plurality of temperature control channels 3, and the plurality of temperature control channels 3 can be in a zigzag shape.

Specifically, the temperature control channel 3 can successively include a first segment, a second segment, and a third segment, which can be communicated with each other. A first end of the second segment can be connected to the first segment, and a second end of the second segment can be connected to the third segment. The first segment and the third segment can extend along the direction of the axis of the epitaxial growth device 100, and the second segment can be in a ring shape, and the second segment in the ring shape can be close to the edge of the tray 2. The cooling medium can flow into the temperature control channel 3 via an inlet of the first segment, and cool the edge of the edge of the tray 2 when flowing through the second segment. Then the cooling medium can discharge from the third segment. The temperature control channel 3 with three segments can be easy to import and discharge the cooling medium. By designing the second segment in the ring shape disposed corresponding to the edge of the tray 2, a relatively high temperature at the edge of the tray 2 can be reduced accurately, thereby accurately controlling temperature at corresponding positions.

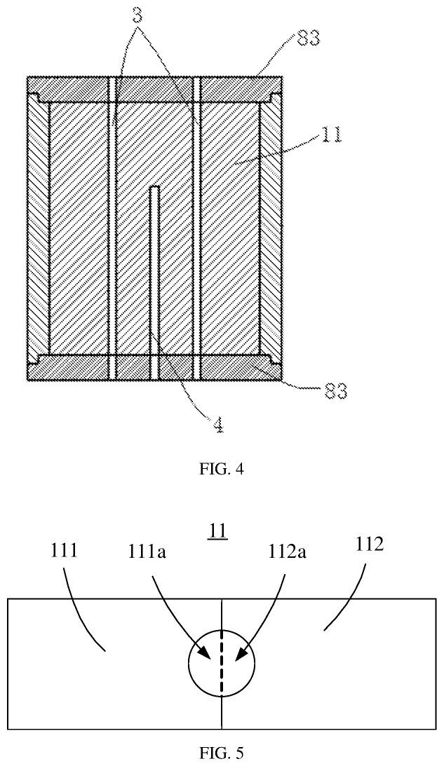

In an embodiment of the present disclosure, referring to FIG. 1, FIG. 2, and FIG. 4, the supporting base 11 can include two temperature control channels 3, the two temperature control channels 3 can be disposed corresponding to two sides of the tray 2 respectively, and the two temperature control channels 3 can control temperatures of the two sides of the tray 2. The two temperature control channels 3 can extend along the direction of the axis of the epitaxial growth device 100 to match with a piping outside the epitaxial growth device 100 for importing and discharging the cooling medium.

Referring to FIG. 1 to FIG. 4, a mounting groove is disposed on the supporting base 11, a locating column 14 is disposed at an axis of the mounting groove 13, and the locating column 14 can extend along a first direction. The tray 2 can rotate on the locating column 14, and the tray 2 is coaxial with the locating column 14.

Referring to FIG. 2, the supporting base 11 can include an air floating channel 4 which is in communication with the mounting groove 13 and an external of the heating body 1 respectively. A number of strip grooves can be spirally distributed on a bottom of the tray 2 (not shown). In a vacuum condition, a small flow of gas can flow into the air floating channel 4, and the gas can drive the tray 2 to levitate and rotate circumferentially with the locating column 14 as a center. The substrate placed on the tray 2 can be driven to rotate, ensuring uniform heating of the substrate in an epitaxial growth process and uniform airflow distribution on the substrate to achieve thickness uniformity of the epitaxial layer. Specifically, when flow rates of inert gas in a plurality of air floating channels 4 are the same, rotating speeds of corresponding trays 2 can be the same. Thus, temperature uniformity and airflow uniformity of the plurality of trays 2 can be improved effectively, thereby ensuring thickness uniformity of epitaxial layers generated on a plurality of substrates and consistent quality of productions in the same batch. The air floating channel 4 can be located between the two temperature control channels 3, and the two temperature control channels 3 can be symmetrically arranged with the air floating channel 4 as an axis.

Alternatively, a flow rate of the cooling medium flowing into the temperature control channel 3 can be less than 1 L/min, avoiding the flow rate of the cooling medium being too great to cause a local cooling of the tray 2 to be enhanced, so as to reduce a temperature difference between an edge of the substrate and a center of the substrate. In other embodiments, the flow rate of the cooling medium flowing into the temperature control channel 3 is not limited to the above 1 L/min, the flow rate of the cooling medium can be controlled according to the temperature difference between the edge of the substrate and the center of the substrate.

Furthermore, referring to FIG. 5, the supporting base 11 can include a first portion 111 and a second portion 112, the first portion 111 can include a first groove 111a, the second portion 112 can include a second groove 112a, the first groove 111a and the second groove 112a can be matched with each other, and the temperature control channel 3 can be defined by the first groove 111a and the second groove 112a. When a structure of the temperature control channel 3 is complicated, the first portion 111 and the second portion 112 can be processed respectively, and then connected to form the temperature control channel 3, so as to simplify a processing and reduce processing difficulty.

Specifically, the first groove is disposed on the first portion, the second groove is disposed on a surface opposite to the first portion of the second portion, and the temperature control channel 3 can be defined by the first groove and the second groove. When the structure of the temperature control channel 3 is complicated, for example, the temperature control channel 3 is in a ring shape, it is difficult to directly form the temperature control channel 3 in the supporting base 11. The first groove and the second groove can be formed respectively, and then connected to form the temperature control channel 3, significantly reducing the difficulty of processing the temperature control channel 3. In other embodiments, the processing of the temperature control channel 3 is not limited to the above.

Furthermore, referring to FIG. 1 and FIG. 2, the heating body 1 has at least one reaction chamber 5 in the present disclosure. A surface of the supporting base 11 configured to support the tray 2 is defined as a chamber wall of the at least one reaction chamber 5. Reaction gas can flow into the at least one reaction chamber 5 to react and produce the epitaxial layer on the substrate.

Referring to FIG. 1 to FIG. 3, when the heating body 1 has a plurality of reaction chambers 5, each reaction chamber 5 can be corresponding to one supporting base 11, and adjacent two reaction chambers 5 can share a single supporting base 11. For example, along a direction perpendicular to the axis of the epitaxial growth device 100, a surface of the supporting base 11 configured to support the tray 2 can be a chamber wall of a first reaction chamber 5, another corresponding surface of the supporting base 11 can be a chamber wall of a second reaction chamber 5, and the first reaction chamber 5 is adjacent to the second reaction chamber 5. Since the adjacent two reaction chambers 5 share one single supporting base 11, the heat generated by the supporting base 11 can be fully used, improving thermal energy utilization.

Along an axis of the induction coil (i.e., the axis of the epitaxial growth device 100), a magnetic field formed within the induction coil varies in strength. When a plurality of reaction chambers 5 are arranged along a direction of the axis of the induction coil, the magnetic fields in which the plurality of reaction chambers 5 are located can be different, resulting in large temperature differences of corresponding trays 2 in the plurality of reaction chambers 5 and large quality differences of the same batch of productions produced by the epitaxial growth device 100. Referring to FIG. 1 to FIG. 3, in the present disclosure, a plurality of supporting bases 11 can be sequentially arranged along a direction perpendicular to the axis of the epitaxial growth device 100, and the plurality of supporting bases 11 are located in the same magnetic field. The plurality of supporting bases 11 can share the induction coil, so as to reduce temperature differences among the plurality of supporting bases 11. Temperatures corresponding to the plurality of trays 2 can be equalized, improving quality of the productions and reducing the variation of the same batch of productions. In other embodiments, the direction along which the plurality of supporting bases 11 are arranged is not limited to the above direction, and the plurality of supporting bases 11 can be arranged along the axis of the induction coil.

In an embodiment of the present disclosure, referring to FIG. 1 to FIG. 3, the heating body 1 can include a plurality of sub-heating bases 12. The sub-heating bases 12 can receive the electromagnetic induction of the induction coil to generate heat to ensure sufficient heating of the reaction chamber 5, improving a heating capacity of the heating body 1. The sub-heating bases 12 configured to support the tray 2 can be the above supporting base 11, adjacent two sub-heating bases 12 are combined to form the reaction chamber 5.

Specifically, referring to FIG. 1 and FIG. 2, the heating body 1 can include three sub-heating bases 12, i.e., a first sub-heating base 121, a second sub-heating base 122, a third sub-heating base 123. Adjacent two sub-heating bases 12 are combined to form a reaction chamber 5, and the second sub-heating base 122 and the third sub-heating base 123 are configured to support the tray 2. In other words, both the second sub-heating base 122 and the third sub-heating base 123 are supporting bases 11. In other embodiments, a specific structure of the heating body 1 is not limited to that described above or shown in the figures. For example, the heating body 1 can also be an integrated structure.

Furthermore, the heating body 1 can have an axisymmetric structure. The heating body 1 as a whole is approximately symmetrically distributed relative to the axis of the induction coil to reduce temperature differences among the plurality of reaction chambers 5. Specifically, referring to FIG. 1 and FIG. 2, the shape of the first sub-heating base 121 and the shape of the third sub-heating base 123 can be the same. For example, both the first sub-heating base 121 and the third sub-heating base 123 can be in a crescent shape, and the second sub-heating base 122 can be in a plate shape. The first sub-heating base 121 and the third sub-heating base 123 are combined to form a neatly cylindrical structure, and a side wall of the cylindrical structure is sufficiently close to a side of the induction coil, resulting in that the induction coil has good magnetic coupling with the heating base 12. In other embodiments, shapes of the first sub-heating base 121 and the third sub-heating base 123 are not limited to the above shape. For example, the first sub-heating base 121, the second sub-heating base 122 and the third sub-heating base 123 can have different shapes, the second sub-heating base 122 can be in a crescent shape, the third sub-heating base 123 can be in a plate shape, and the third sub-heating base 123 can be supported by the second sub-heating base 122. It could be understood that in other embodiments, a shape of the heating base 12 is not limited to that described above or shown in the figures, but may also be in other shapes.

Alternatively, along a direction perpendicular to the axis of the induction coil, through holes 7 are disposed in the heating bases 12 at a top and a bottom of the heating body 1, and the through holes 7 can extend along the axis of the induction coil. It could be understood that the through holes 7 are beneficial to reduce a mass of the heating base 12 and reduce thermal inertia of the heating base 12. Particles shed from an inner wall of the through-holes 7 can be removed by importing gas along the through-holes 7, and the imported gas can be further configured to finely tune a temperature of the heating base 12. Specifically, referring to FIG. 1 and FIG. 2, the through-holes 7 are disposed in the first sub-heating base 121 and the third sub-heating seat 123.

Referring to FIG. 1 and FIG. 2, the heating body 1 can further include a supporting member 6 disposed between any adjacent two supporting bases 12, and the supporting member 6 can act as a side wall of the reaction chamber 5. The supporting member 6 is configured to support the heating base 12 and/or control a height of the reaction chamber 5.

An epitaxial growth device 100 can be further provided in the present disclosure, which can include any one of the above heating bodies 1.

Furthermore, the epitaxial growth device 100 can further include a heat retaining cylinder 8 and the induction coil. The heating body 1 is installed in the heat retaining cylinder 8, which facilitates an insulation of the heating body 1 from an external environment, reducing heat loss and improving a sealing performance of the heating body 1. In addition, the induction coil is disposed around an outside of the heat retaining cylinder 8.

The heat retaining cylinder 8 can include a first heat retaining felt 81, a second heat retaining felt 82 and two end caps 83. The two end caps 83 can cover two ends of the first heat retaining felt 81 and the second heat retaining felt 82 respectively, and can be enclosed with the first heat retaining felt 81 and the second heat retaining felt 82 into the heat retaining cylinder 8. Alternatively, a first step 84 is disposed on the first heat retaining felt 81, and a second step 85 corresponding to the first step 84 is disposed on the second heat retaining felt 82. When the first heat retaining felt 81 and the second heat retaining felt 82 are assembled, the first step 84 and the second step 85 are embedded with each other to allow the first heat retaining felt 81 and the second heat retaining felt 82 to fit together to form the heat retaining cylinder 8. In other embodiments, a connecting way of the heat retaining felt 81 and the second heat retaining felt 82 is not limited to the above way. For example, the heat retaining felt 81 and the second heat retaining felt 82 are in an integrated structure, a snap structure or other connecting structures.

The technical features of the above-described embodiments may be combined in any combination. For the sake of brevity of description, not all possible combinations of the technical features in the above embodiments are described. However, as long as there is no contradiction between the combinations of these technical features, all should be considered as within the scope of this disclosure.

The above-described embodiments are merely illustrative of several embodiments of the present disclosure, and the description thereof is relatively specific and detailed, but is not to be construed as limiting the scope of the disclosure. It should be noted that a number of variations and modifications may be made by those skilled in the art without departing from the spirit and scope of the disclosure. Therefore, the scope of the disclosure should be determined by the appended claims.

We claim:

1. A heating body of an epitaxial growth device configured to heat a substrate, comprising a supporting base and a tray,
wherein the supporting base comprises at least one temperature control channel which is hollow and penetrates through the supporting base along an axis of the epitaxial growth device;
the tray is mounted on the supporting base to support a substrate;
the temperature control channel is configured to accommodate a temperature control medium, and the temperature control medium is able to be input and output via two ends of the temperature control channel respectively, so as to control an environment temperature of the tray.

2. The heating body of the epitaxial growth device of claim 1, wherein the temperature control channel is close to an edge of the tray, and along a direction perpendicular to a surface of the supporting base, a part of a projection of the temperature control channel is on the tray.

3. The heating body of the epitaxial growth device of claim 1, wherein the supporting base comprises one temperature control channel, and a part of the temperature control channel is in a ring shape.

4. The heating body of the epitaxial growth device of claim 3, wherein the temperature control channel successively comprises a first segment, a second segment, and a third segment, which are in communication with each other; the second segment is in a ring shape, and the second segment is close to an edge of the tray.

5. The heating body of the epitaxial growth device of claim 1, wherein the supporting base comprises two temperature control channels, and the two temperature control channels are disposed corresponding to two sides of the tray respectively.

6. The heating body of the epitaxial growth device of claim 5, wherein the supporting base comprises an air floating channel which is located between the two temperature control channels, and the two temperature control channels are symmetrically arranged with the air floating channel as an axis.

7. The heating body of the epitaxial growth device of claim 1, wherein the supporting base comprises a first portion and a second portion, the first portion comprises a first groove, the second portion comprises a second groove, the first groove and the second groove are matched with each other, and the temperature control channel is defined by the first groove and the second groove.

8. The heating body of the epitaxial growth device of claim 1, wherein the heating body comprises a plurality of supporting bases, the plurality of the supporting bases are sequentially arranged along a direction perpendicular to the axis of the epitaxial growth device.

9. The heating body of the epitaxial growth device of claim 8, wherein the heating body further comprises a supporting member disposed between adjacent two adjacent supporting bases.

10. An epitaxial growth device, comprising the heating body of claim 1.

11. The epitaxial growth device of claim 10, wherein the temperature control channel is close to an edge of the tray, and along a direction perpendicular to a surface of the supporting base, a part of a projection of the temperature control channel is on the tray.

12. The epitaxial growth device of claim 10, wherein the supporting base comprises one temperature control channel, and a part of the temperature control channel is in a ring shape.

13. The epitaxial growth device of claim 12, wherein the temperature control channel successively comprises a first segment, a second segment, and a third segment, which are in communication with each other; the second segment is in a ring shape, and the second segment is close to an edge of the tray.

14. The epitaxial growth device of claim 10, wherein the supporting base comprises two temperature control channels, and the two temperature control channels are disposed corresponding to two sides of the tray respectively.

15. The epitaxial growth device of claim 14, wherein the supporting base comprises an air floating channel which is located between the two temperature control channels, and the two temperature control channels are symmetrically arranged with the air floating channel as an axis.

16. The epitaxial growth device of claim 10, wherein the supporting base comprises a first portion and a second portion, the first portion comprises a first groove, the second portion comprises a second groove, the first groove and the second groove are matched with each other, and the temperature control channel is defined by the first groove and the second groove.

17. The epitaxial growth device of claim 10, wherein the heating body comprises a plurality of supporting bases, the plurality of the supporting bases are sequentially arranged along a direction perpendicular to the axis of the epitaxial growth device.

18. The epitaxial growth device of claim 17, wherein the heating body further comprises a supporting member disposed between adjacent two adjacent supporting bases.
